(19) United States
(12) Patent Application Publication
(10) Pub. No.: US 2006/0062291 A1
(43) Pub. Date: Mar. 23, 2006

(54) Digital pulse width modulated controller

(75) Inventors: Joseph A. Marotta, Boonton, NJ (US); Donald J. Porawski, Cedar Grove, NJ (US)

Correspondence Address: KURT A. LUTHER;HONEYWELL INTERNATIONAL, INC, LAW DEPARTMENT AB2, P.O. BOX 2245, MORRISTOWN, NJ, 07962-2245, US

(73) Assignee: Honeywell International Inc.

(21) Appl. No.: 10/943,976

(22) Filed: Sep. 20, 2004

(51) Int. Cl. H03K 7/08

(52) U.S. Cl. 375/238

(57) ABSTRACT

Embodiments of the present invention provide a closed loop control system that is capable of handling a wide variety of loads. In some embodiments, the control system uses a pulse width modulated (PWM) signal to drive a plant. The PWM signal has a switching frequency. A feedback signal is measured from the plant and provided back to controller. The feedback signal may be converted into a digital feedback signal based on oversampling the feedback signal at a multiple, such as twice, of the switching frequency of the PWM signal. The digital feedback signal may then be filtered to reduce or remove any unwanted components. For example, the digital feedback signal may be passed through a notch filter that suppresses a range of frequencies centered around the switching frequency of the PWM signal. In addition, the digital feedback signal may be passed through a digital low pass filter. Based on the filtered digital feedback signal, the controller may then adjust the PWM signal delivered to the plant.

### FIELD

This invention relates to a control system, and more particularly, it relates to a digital pulse width modulated control system.

### INTRODUCTION

Control systems are widely used to control many types of devices and applications from household appliances to large industrial machines including ships, power plants, and aircraft. For example, in aircraft, a control system may be used to control various types of loads, such as, motors, direct drive valves, autothrottles, wing flaps, ailerons, and the rudder.

Typically, these loads are analog in nature, but are controlled by a digital processor or controller. In order to interface with an analog circuit, a digital controller may use a pulse width modulated (PWM) signal as a control signal to drive the analog circuit. A PWM signal can be used to digitally encode an analog signal level based on varying the width of its pulses. The PWM signal has a switching frequency and its duty cycle is modulated to encode a specific analog signal level. The PWM signal can then be delivered as series of voltage or current pulses to drive an analog circuit. Therefore, a digital processor or controller may control an analog circuit digitally based on a PWM signal.

In addition, most control systems utilize a feedback loop in order to optimize the control signal that is provided to the analog circuit. These control systems are also known as closed loop control systems. In a closed loop control system, a sensor is connected to the analog circuit or its load and generates a feedback signal. The feedback signal may represent, for example, a position, voltage, temperature, or any other appropriate parameter of the analog circuit or load. The feedback signal may then be sampled and converted into a digital signal that is fed back to the controller. The controller may then adjust its control signal based on this feedback.

In some conventional control systems, a notch filter may be used to attenuate the mechanical resonance caused by the components in the plant. For example, U.S. Pat. No. 5,875,158 to Schell entitled, “Servo Control System for Information Storage Device,” describes a control system that employs a notch filter to notch parasitic mechanical resonance frequencies of a servo mechanism. However, such a control system with this notch filter fails to compensate for frequency components in the feedback signal that result from PWM signals.

Unfortunately, closed loop control systems that use PWM signals can become unstable in various applications. For example, a PWM closed loop control system can become unstable when driving a load that has a wide variance in its inductive load, such as a direct drive valve in triplex mode. A triplex mode direct drive valve uses three inductive loads connected in parallel around a common motor core. During operation, the windings each generate a magnetic flux from the PWM signal. The fluxes from each of the windings add to each other and produce a torque in the motor that translates into motion by the valve. This arrangement allows for redundancy, because if one winding fails, the other windings can be driven at a higher level to make up any difference.

However, this arrangement also causes challenges for the controller. For example, the three windings often cause mutual inductance with each other and their inductive load can vary widely. In addition, the nature of the PWM signal often creates noise in the feedback signal at its switching frequency or at its harmonic frequencies. This can be a problem at low inductances because the control system can become unstable over time.

Therefore, it would be desirable to provide methods, apparatus and systems that are capable of controlling a wide variety of loads, such as varying inductive loads. In addition, it would be desirable, among other things, to provide a way minimize the effect of PWM noise in the feedback of a closed loop control system.

### SUMMARY

In accordance with embodiments of the present invention, a plant may be controlled based on a pulse width modulated drive signal having a switching frequency. The pulse width modulated signal is applied to drive the plant. A feedback signal that indicates the response of the plant is measured. The feedback signal is converted into a digital feedback signal based on sampling the feedback signal at a multiple of the switching frequency of the digital pulse modulated signal to form a digital feedback signal. A range of frequencies centered around the sampling frequency are filtered in the digital feedback signal to form a control signal. The pulse modulated signal is then adjusted based on the control signal.

In accordance with other embodiments of the present invention, a controller is configured to provide a pulse width modulated drive signal to a plant that is controlled based on a feedback signal. The pulse modulated drive signal has a switching frequency and the feedback signal is sampled at a multiple of the switching frequency to form a digital feedback signal. A notch filter is configured to selectively suppress a range of frequencies centered around the switching signal in the digital feedback signal. A digital low pass filter is configured to selectively pass frequencies less than a cutoff frequency from the output of the notch filter. A lead-lag compensator circuit, such as a Digital Signal Processor Integrator circuit, is configured to generate a control signal based on the output of the digital low pass filter. A pulse width modulator circuit is then configured to generate the pulse width modulated drive signal based on the output of the integrator circuit.

In accordance with other embodiments of the present invention, a system is configured to control a load. A driver powers the load based on a pulse width modulated signal having a switching frequency. A sensor generates a feedback signal based on the response of the driver and the load. A converter converts the feedback signal into a digital feedback signal based on oversampling the feedback signal at a multiple of the switching frequency. A controller generates the pulse width modulated signal based on selectively suppressing a range of frequencies centered around the switching frequency in the digital feedback signal.

Additional features of the invention will be set forth in part in the description which follows, and in part will be obvious from the description, or may be learned by practice of the invention. The features of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments and features of the invention and together with the description, serve to explain the principles of the invention.

FIG. 1 illustrates an exemplary control system that is consistent with embodiments of the present invention;

FIG. 2 illustrates an exemplary controller that is consistent with embodiments of the present invention;

FIG. 2A shows frequency responses of examples of notch filters that are consistent with embodiments of the present invention;

FIG. 3 illustrates an exemplary notch filter that is consistent with embodiments of the present invention;

FIG. 4 illustrates an exemplary feed-forward digital low pass filter that is consistent with the principles of the present invention; and

FIG. 5 illustrates an exemplary digital lead-integrator that is consistent with embodiments of the present invention.

### DESCRIPTION OF THE EMBODIMENTS

Embodiments of the present invention provide a closed loop control system that is capable of handling a wide variety of loads. In some embodiments, the control system uses a PWM signal with a switching frequency to drive a plant. A plant is any element that is controlled by the control system. For example, the plant may be any device, process, circuit, or machine, of which a particular parameter or condition is to be controlled. A feedback signal is measured from the plant and provided back to controller. The feedback signal may be converted into a digital feedback signal based on oversampling the feedback signal at a multiple, such as twice, of the switching frequency of the PWM signal. The digital feedback signal may then be filtered to reduce or remove any unwanted components. For example, the digital feedback signal may be passed through a notch filter that is configured to suppress a range of frequencies centered around the switching frequency of the PWM signal. In addition, the digital feedback signal may be passed through a digital low pass filter. Based on the filtered digital feedback signal, the controller may then adjust the PWM signal delivered to the plant.

The features of the invention will now be set forth in part in the description which follows, and in part will be obvious from the description, or may be learned by practice of the invention. Both the foregoing general description and the following detailed description are exemplary and explanatory only and are not restrictive of the invention, as claimed.

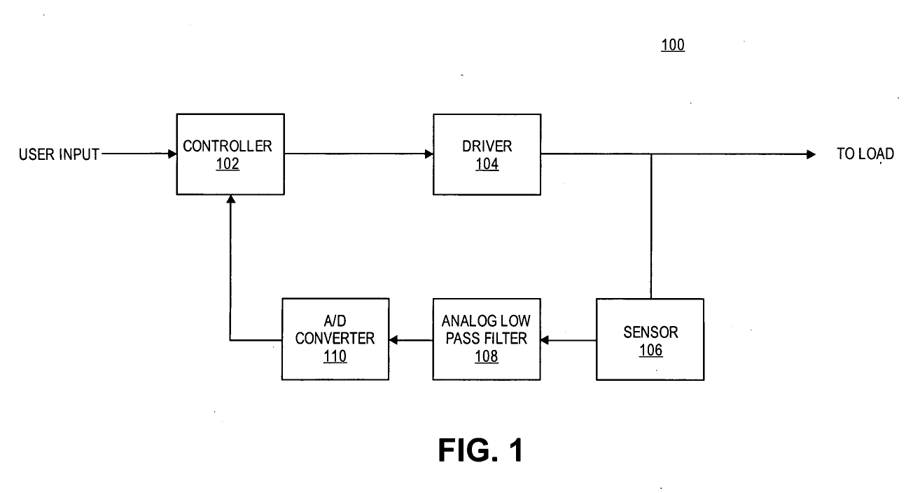

FIG. 1 illustrates an exemplary control system 100 that is consistent with embodiments of the present invention. As shown, control system 100 may include a controller 102, a driver 104, a sensor 106, an analog low pass filter 108, and an analog-to-digital (A/D) converter 110. These components may be coupled to each other either directly or indirectly. For example, the components of control system 100 may be coupled together over a bus or through wiring. The components of control system 100 will now be further described.

Controller 102 includes the hardware and software for controlling driver 104 and a load (not shown). In some embodiments, controller 102 employs a PWM signal to control driver 104. For example, controller 102 may employ a 40 KHz PWM signal to control driver 104.

Controller 102 may be implemented using a processor or programmable logic controller. For example, controller 102 may be a microprocessor based device having either modular or integrated circuitry that monitors the status of driver 104 and its associated loads and modifies its output to driver 104. In some embodiments, controller 102 is implemented as a field programmable gate array (FPGA). Alternatively, controller 102 may be implemented as other types of devices, such as an applications specific integrated circuit or general purpose microprocessor. In addition, controller 102 may include a memory or storage (not shown) to store software and data collected, for example, from sensor 106.

Driver 104 provides power to the load (not shown) based on the control signal from controller 102. For example, driver 104 may be implemented as an H-bridge circuit that operates based on a PWM signal from controller 102. In some embodiments, the switching frequency of driver 104 may be based on dividing the maximum clock frequency of the FPGA used in controller 102 by the desired output resolution. For example, if the desired output resolution of sensor 104 is 0.75 ma/bit and the maximum output drive is ±1.5 Amps, then the resolution is equal to ±2000 or 4000. For a maximum FPGA clock frequency of 160 MHz, this results in a switching frequency of 160 Mhz/4000, which is equal to 40 Khz. Thus, in this example, driver 104 may operate based on a switching frequency of 40 Khz. However, any switching frequency may be used for driver 104 in accordance with the principles of the present invention.

In addition, in some embodiments, driver 104 may ground both sides of the load during for a certain period of time to minimize the effect of noise. After the period of time has passed, driver 104 may then release both sides of the load. Embodiments of the present invention may use any type of circuitry for driver 104 and such other types of drivers are well known to those skilled in the art.

Sensor 106 measures the response of driver 104 and the load to the control signal from controller 102 and produces a feedback signal. In some embodiments, sensor 106 is implemented as an analog sensor. For example, sensor 106 may be implemented as a set of current sensing resistors (not shown) that are coupled to driver 104. Current flowing through the sensing resistors result in a voltage that is then output by sensor 106. In order to optimize the accuracy of the measured signal, sensor 106 may also include other components, such as filters, and voltage rectifiers. Of course, one skilled in the art will recognize that any type of sensor may be used in accordance with the principles of the present invention. For example, U.S. Pat. No. 5,703,490, entitled “Circuit and Method for Measuring Current in an H-Bridge Drive Network,” and issued to the same assignee illustrates one example of a sensor that may be used with embodiments of the present invention. Of course one skilled in the art will recognize that other embodiments may use other types of circuits, such as half bridge circuits.

Analog low pass filter 108 is an optional component of control system 100 and may be used to filter the high frequency portion of the feedback signal and pass low frequency components that are less than a cutoff frequency from sensor 106. Filtering of high frequency portions may be considered useful to some embodiments of the present invention because noise and other undesirable effects in a feedback signal are often characterized as high frequency phenomenon. Analog low pass filter 108 may be implemented using well known components, such as resistors and capacitors, to filter high frequencies.

A/D converter 110 converts the feedback signal into a digital feedback signal. A/D converter 110 may operate based on sampling the feedback signal at various sampling rates and encoding the signal level based on any number of bits. For example, in some embodiments, A/D converter 110 may oversample the feedback signal at twice the frequency of the PWM signal used by controller 102.

In general, conventional closed loop control systems use analog low pass filters on the feedback signals to reject components at the switching frequency of the system. However, conventional control systems sample their feedback signals at a frequency high enough to meet the performance requirements of the closed loop bandwidth, such as a closed loop phase shift. However, the closed loop bandwidth of closed loop systems is usually much lower than the switching frequency. Therefore, conventional closed loop control systems sample their feedback signals at rates much lower than their switching frequency. As will be explained below, some embodiments of the present invention may oversample the feedback signal at a higher rate in order to reduce or remove noise or undesirable components. For example, embodiments of the present invention may be used to filter the feedback signal to remove or attenuate components resulting from the switching frequency of driver 104.

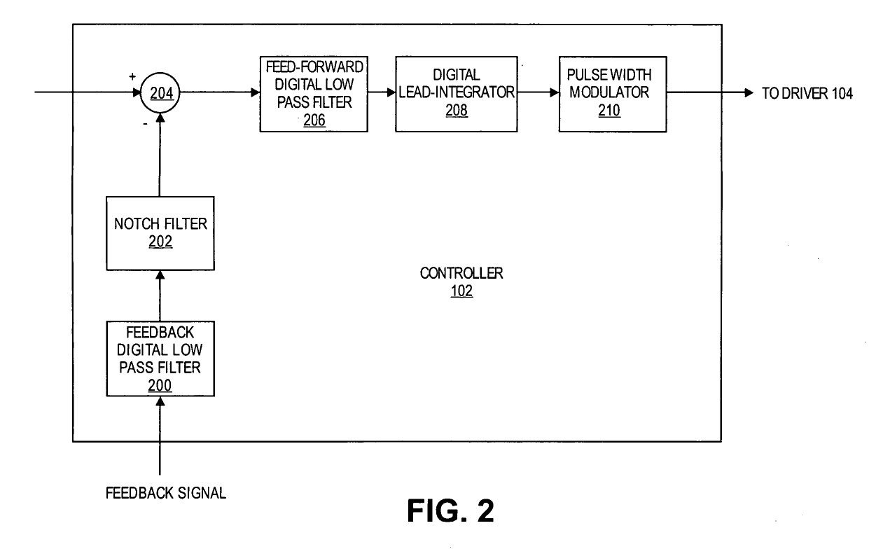

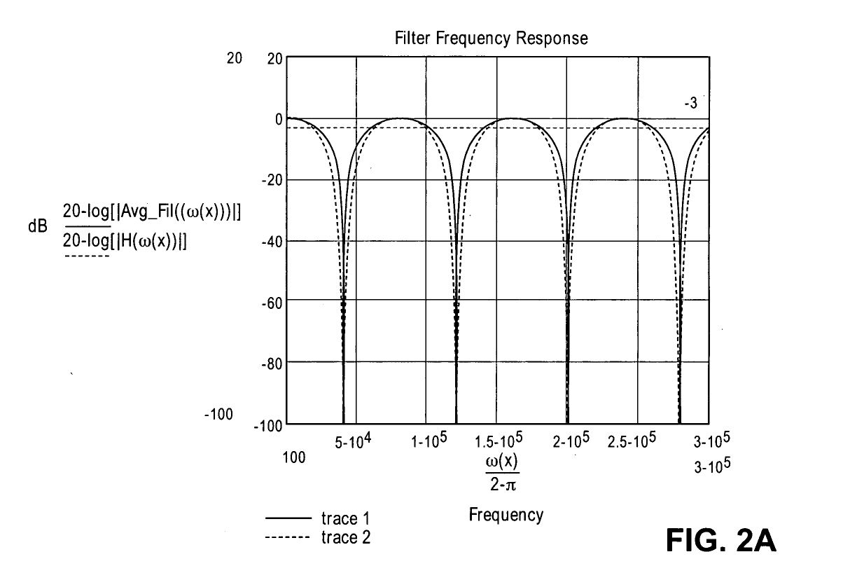

FIG. 2 illustrates an example of controller 102 that is consistent with embodiments of the present invention. As shown, controller 102 may include a feedback digital low pass filter 200, a notch filter 202, a summer 204, a feed-forward digital low pass filter 206, a digital lead-integrator 208, and a pulse width modulator 210.

Feedback digital low pass filter 200 filters high frequency components and passes frequencies less than a cutoff frequency in the digital feedback signal. Digital low pass filter 200 may be implemented with well known components.

Notch filter 202 removes or suppresses a narrow slice from the received digital feedback signal. In some embodiments, since the digital feedback signal is based on oversampling the feedback signal at a multiple of the frequency of the PWM signal, notch filter 202 can be configured to reduce the gain or amplitude of a narrow band of frequencies centered around the switching frequency of the PWM signal of controller 102. For example, the digital feedback signal may be oversampled at twice the frequency of the PWM signal. Of course, one skilled in the art will recognize that notch filter 202 may be configured as a higher order filter, and thus, oversample the digital feedback signal at even higher rates. This may be useful, among other things, to help reduce the noise induced in the feedback by the PWM signal.

For example, when implemented as a second order filter, notch filter 202 can be theoretically characterized by the transfer function of:

$$H ( s ) = \frac{1}{( s + a ) \cdot ( s + \overline{a} )}$$

where a=e^{-jω/4} and \overline{a} is the complex conjugate of a.

One can then apply the Matched Z transform to this equation and solve to obtain the following equation for notch filter 202 of:

$$H ( z ) = [ \frac{[ {( 1 + {z}^{- 1} )}^{2} ]}{[ ( s + \sqrt{2} ) + ( 2 - \sqrt{2} ) \cdot {z}^{- 2} ]} ]$$

From this equation for H(z), it can be seen that the transfer function has a double zero at ½ the sampling frequency, i.e., where (1+z⁻¹)²=0. Therefore, if the sample frequency is equal to twice the switching frequency, then notch filter 202 may theoretically infinitely attenuate the switching frequency and odd harmonics of the switching frequency. Of course one skilled in the art will recognize that notch filter 202 may be implemented based on known components having round off errors and timing errors and, thus, having a finite attenuation characteristic. Notch filter 202 may also fold the even harmonies of the switching frequency back to DC, and thus, converge these components to a small value since harmonics tend to be bipolar. Examples of the frequency responses of various implementations of notch filter 202 are shown with reference to FIG. 2A.

In other embodiments, notch filter 202 may be implemented as a DSP filter that is configured as an averaging filter with the following transfer function:

$$Y ( n ) = \frac{X ( n ) + X ( n - 1 )}{2} H ( z ) = 0.5 \cdot ( 1 + z )$$

In these embodiments, notch filter will also have a theoretical infinite attenuation of the switching frequency when the sample frequency is set equal to twice the switching frequency. This filter will have similar characteristics to the one described above except it has a single zero and the attenuation may be less steep.

Accordingly, notch filter 202 can be characterized as a filter that suppresses components at half (½) of the sampling frequency. Exploiting this feature of notch filter 202, the sampling frequency of the feedback signal can be set to twice the switching frequency of the PWM signal, and therefore, the noise induced by the PWM signal can be minimized or removed. As noted above, notch filter 202 may be configured as a higher order filter, and thus, the digital feedback signal may be oversampled by other multiples of the frequency of the PWM signal. Other advantages of various configurations for notch filter 202 may also be apparent to those skilled in the art.

Summer 204 adds the output of notch filter 202 with an input signal to controller 102. For example, a user or external device may provide an input signal to controller 102 to adjust the operation of driver 104. Summer 204 may be implemented using well known components.

Feed-forward digital low pass filter 206 is coupled to the output of summer 204 and filters high frequency components and passes low frequency components less than a cutoff frequency. Feed-forward digital low pass filter 206 may also be implemented using well known components.

Digital lead-integrator 208 integrates the filtered digital feedback signal and forms a signal for pulse width modulator 210 that indicates the desired pulse width of the control signal. Pulse width modulator 210 then forms the PWM control signal and delivers it to driver 104. Digital lead-integrator 204 and pulse width modulator 210 may be implemented using well known components.

FIG. 2A shows the frequency responses of examples of notch filter 202 that is consistent with embodiments of the present invention. As shown, notch filter 202 may be configured to sharply attenuate certain frequencies as well as harmonics of those frequencies. In particular, the trace drawn in solid lines (trace 1) shows the frequency response of notch filter 202 when it is configured as an averaging filter. The trace shown in dotted lines (trace 2) shows the frequency response of notch filter 202 when it is configured as the notch filter described above with reference to FIG. 2.

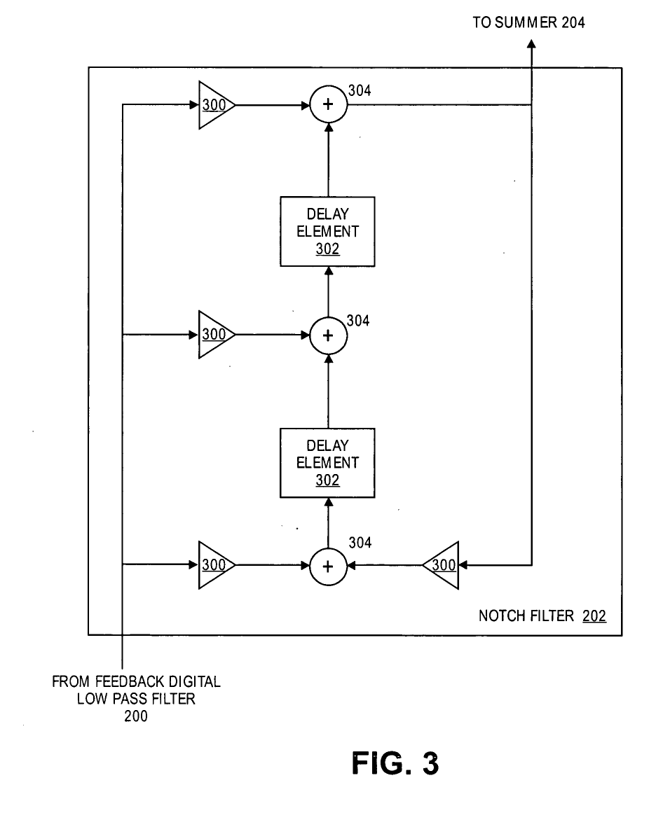

FIG. 3 illustrates an example of notch filter 202 that is consistent with embodiments of the present invention. As shown, notch filter 202 may comprise a set of multipliers 300, delay elements 302, and summers 304. FIG. 3 merely illustrates one arrangement for notch filter 202. One skilled in the art will recognize that other components and arrangements may be used for notch filter 202.

Multipliers 300 multiply the value of the digital feedback signal by a set constant. In some embodiments, each of multipliers 300 may be configured with different constant. These constant values may be downloaded into multipliers 300, for example, from a set of registers (not shown) in controller 102. One skilled in the art will recognize that various constant values may used in order to optimize the performance of notch filter 202.

Delay elements 302 and summers 304 implement the filtering calculations of notch filter 202. One skilled in the art will recognize that delay elements 302 and summers 304 may be based on well known components, such as flip-flops, operation amplifiers, and the like. Of course, other arrangements for notch filter 202 are also consistent with embodiments of the present invention.

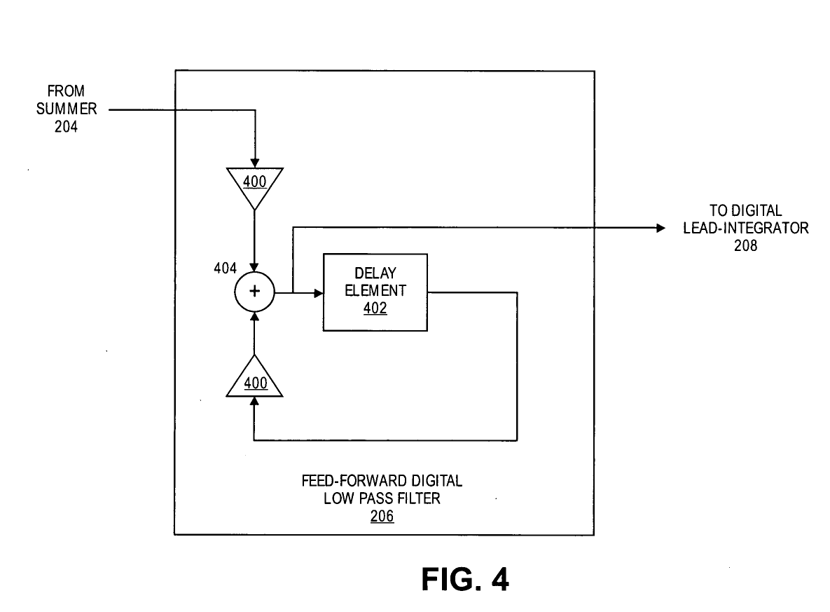

FIG. 4 illustrates an example of feed-forward digital low pass filter 206 that is consistent with the principles of the present invention. As shown, digital low pass filter 206 may include multipliers 400, a delay element 402, and a summer 404.

Multipliers 400 multiply the value of the signal from summer 204 by a set constant. In some embodiments, each of multipliers 400 may also be configured with different constant. In addition, these constant values may be downloaded into multipliers 400 from a set of registers (not shown) in controller 102. One skilled in the art will recognize that various constant values may used in order to optimize the performance of digital low pass filter 206.

Delay element 402 and summer 404 implement the low pass filtering calculations of digital low pass filter 206. One skilled in the art will recognize that these components may be implemented using well known components. Of course, other arrangements for feed-forward digital low pass filter 206 are also consistent with embodiments of the present invention.

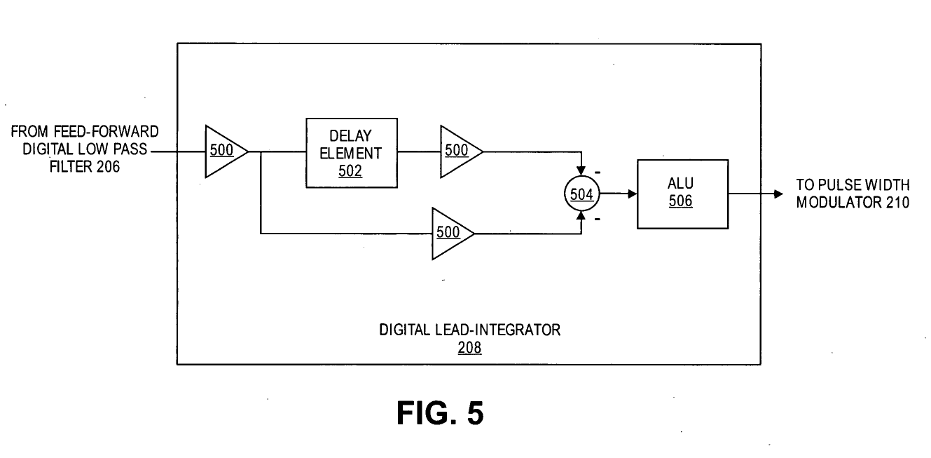

FIG. 5 illustrates an example digital lead-integrator 208 that is consistent with embodiments of the present invention. As shown, digital lead-integrator 208 can include multipliers 500, a delay element 502, a summer 504, and an arithmetic logic unit (ALU) 506.

Multipliers 400 multiply the value of the signal from feed-forward digital low pass filter 206 by a set constant. In some embodiments, each of multipliers 500 may also be configured with different constant. In addition, these constant values may be downloaded into multipliers 500 from a set of registers (not shown) in controller 102. One skilled in the art will recognize that various constant values may used in order to optimize the performance of digital lead-integrator 208.

Delay element 502, summer 504, and ALU 506 implement the calculations to determine the pulse width that is to be used by pulse width modulator 210. One skilled in the art will recognize that these components may be implemented using well known components. Of course, other arrangements for digital lead-integrator are also consistent with embodiments of the present invention.

Other features and embodiments of the invention will be apparent to those skilled in the art from consideration of the specification and practice of the invention disclosed herein. It is intended that the specification and examples be considered as exemplary only, with a true scope and spirit of the invention. For example, the control loop of various embodiments may be easily adapted to a wide range of loads by changing the lead-lag integrator constants and gain using digital registers. In addition, in the event of a commanded disconnect, stored energy in the inductive load of a plant may also be dissipated by grounding both sides of the load.

What is claimed is:

1. A method of controlling a plant based on a pulse width modulated drive signal having a switching frequency, said method comprising:
applying the pulse width modulated signal to drive the plant;
measuring a feedback signal that indicates the response of the plant;
converting the feedback signal into a digital feedback signal based on sampling the feedback signal at a multiple of the switching frequency of the digital pulse modulated signal to form a digital feedback signal;
filtering a range of frequencies centered around the switching frequency in the digital feedback signal to form a control signal; and
adjusting the pulse modulated signal based on the control signal.

2. The method of claim 1, wherein filtering the range of frequencies to form the control signal further comprises:
selectively passing frequencies lower than a cutoff frequency in the digital feedback signal to form an intermediate feedback signal; and
filtering the range of frequencies centered around the switching frequency in the intermediate feedback signal to form the control signal.

3. The method of claim 1, further comprising:
grounding both sides of a load coupled to the driver for a period of time.

4. The method of claim 2, further comprising:
releasing both sides of the load after the period of time.

5. A controller configured to provide a pulse width modulated drive signal to a plant that is controlled based on a feedback signal, wherein the pulse modulated drive signal has a switching frequency and wherein the feedback signal is sampled at a multiple of the switching frequency to form a digital feedback signal, said controller comprising:
a notch filter configured to selectively suppress a range of frequencies centered around the switching signal in the digital feedback signal;
a digital low pass filter configured to selectively pass frequencies less than a cutoff frequency from the output of the notch filter;
an integrator circuit configured to generate a control signal based on the output of the digital low pass filter; and
a pulse width modulator circuit configured to generate the pulse width modulated drive signal based on the output of the integrator circuit.

6. The controller of claim 5, further comprising:
at least one additional digital low pass filter coupled to the input of the notch filter that selectively passes frequencies in the digital feedback signal.

7. A system configured to control a load, said system comprising:
a driver that powers the load based on a pulse width modulated signal having a switching frequency;
a sensor that generates a feedback signal based on the response of the driver and the load;
a converter that converts the feedback signal into a digital feedback signal based on oversampling the feedback signal at a multiple of the switching frequency; and
a controller that generates the pulse width modulated signal based on selectively suppressing a range of frequencies centered around the switching frequency in the digital feedback signal.

8. The system of claim 7, wherein the system is configured to control a direct drive valve.

9. The system of claim 7, wherein the driver is configured as an H-bridge circuit.

10. The system of claim 7, wherein the driver is configured to ground both sides of the load for a period of time.

11. The system of claim 10, wherein the driver is configured to release both sides of the load after the period of time.

12. An apparatus for controlling a plant based on a pulse width modulated drive signal having a switching frequency, said apparatus comprising:
means for applying the pulse width modulated signal to drive the plant;
means for measuring a feedback signal that indicates the response of the plant;
means for converting the feedback signal into a digital feedback signal based on sampling the feedback signal at a multiple of the switching frequency of the digital pulse modulated signal;
means for filtering a range of frequencies centered around the switching frequency in the digital feedback signal to form a control signal; and
means for adjusting the pulse modulated signal based on the control signal.

13. The apparatus of claim 12, wherein the means for filtering the range of frequencies to form the control signal further comprises:
means for selectively passing frequencies lower than a cutoff frequency in the digital feedback signal to form an intermediate feedback signal; and
means for filtering the range of frequencies centered around the switching frequency in the intermediate feedback signal to form the control signal.

14. The apparatus of claim 12, further comprising:
means for grounding both sides of a load coupled to the driver for a period of time.

15. The apparatus of claim 15, further comprising:
means for releasing both sides of the load after the period of time.
